(19) United States
(12) Patent Application Publication
(10) Pub. No.: US 2018/0294775 A1
(43) Pub. Date: Oct. 11, 2018

(54) RADIO-FREQUENCY SIGNAL PROCESSING MODULE CAPABLE OF EFFECTIVELY REMOVING POWER INTERFERENCE

(71) Applicant: Chin-Huei YUAN, Taipei City (TW)

(72) Inventor: Shan-Jui LU, New Taipei City (TW)

(21) Appl. No.: 15/600,739

(22) Filed: May 21, 2017

(30) Foreign Application Priority Data
Apr. 5, 2017 (TW) 106111440

(51) Int. Cl. H03F 1/02; H03G 1/00; H03G 3/00; H03F 1/18; H03F 1/42; H02B 1/30; H01R 13/04

(52) U.S. Cl. CPC H03F 1/0211; H03G 1/0005; H03G 3/007; H03F 1/18; H03F 2200/114; H02B 1/30; H01R 13/04; H03F 2200/465; H03F 1/42

(57) ABSTRACT

A radio-frequency signal processing module capable of effectively removing power interference, including: a module body; a circuit board, placed inside the module body; at least one broadband system power connector electrically coupled with the circuit board; and a plurality of radio-frequency connectors electrically coupled with the circuit board for receiving at least one input radio-frequency signal and providing at least one output radio-frequency signal; wherein, the broadband system power connector has a space accommodating at least one filtering device so that interference of a power source can be attenuated and electromagnetic waves resulting from the interference can be dissipated outside the circuit board.

### BACKGROUND OF THE INVENTION

### Field of the Invention

The present invention relates to a radio-frequency signal processing module, especially to a radio-frequency signal processing module capable of effectively removing power interference.

### Description of the Related Art

Please refer to FIG. 1, which illustrates a radio-frequency signal processing module of prior art. As illustrated in FIG. 1, the radio-frequency signal processing module includes a module body 10, a broadband system power connector 20, an input radio-frequency connector 30 and an output radio-frequency connector 40, wherein the module body 10 contains a power filtering device 11 and an active element filtering device 12, wherein the power filtering device 11 is used for filtering out interference of a power source.

Although the power filtering device 11 has a function of filtering out the interference, however, electromagnetic waves resulting from the interference can emit from gaps between the module body 10 and the input radio-frequency connector 30 and the output radio-frequency connector 40 to violate related regulations of electromagnetic interference.

To solve the foregoing problems, a novel radio-frequency signal processing module is needed.

### SUMMARY OF THE INVENTION

One objective of the present invention is to disclose a radio-frequency signal processing module capable of effectively removing power interference, which is capable of promoting the quality of a radio-frequency signal by filtering out interference of a power source with a broadband system power connector.

Another objective of the present invention is to disclose a radio-frequency signal processing module capable of effectively removing power interference, which is capable of effectively reducing an electromagnetic emission over a frequency band by dissipating electromagnetic waves resulting from interference of a power source with a broadband system power connector.

Another objective of the present invention is to disclose a radio-frequency signal processing module capable of effectively removing power interference, which is capable of promoting the quality of a radio-frequency signal by filtering out interference of a power source with an add-on broadband system filtering connector.

Another objective of the present invention is to disclose a radio-frequency signal processing module capable of effectively removing power interference, which is capable of effectively reducing an electromagnetic emission over a frequency band by dissipating electromagnetic waves resulting from interference of a power source with an add-on broadband system filtering connector.

Still another objective of the present invention is to disclose a radio-frequency signal processing module capable of effectively removing power interference, which is also capable of preventing radio-frequency noise from interfering with a power source.

To attain the foregoing objectives, a radio-frequency signal processing module capable of effectively removing power interference is proposed, including:

a module body;

a circuit board, placed inside the module body;

at least one broadband system power connector, each being used for coupling with a power source via a power cable to power the circuit board; and

a plurality of radio-frequency connectors electrically coupled with the circuit board for receiving at least one input radio-frequency signal and providing at least one output radio-frequency signal;

wherein, the broadband system power connector has a space accommodating at least one filtering device so that interference of a power source can be attenuated and electromagnetic waves resulting from the interference can be dissipated outside the circuit board to promote a quality of the at least one output radio-frequency signal and reduce electromagnetic emission over a frequency band.

In one embodiment, the broadband system power connector has an axial metal contact part inside, and the axial metal contact part is a metal clamping piece or a metal pin.

In one embodiment, the module body has at least one port for installing the at least one broadband system power connector.

In one embodiment, the filtering device includes an electromagnetic wave absorbing material, or the broadband system power connector has an electromagnetic wave absorbing material filled inside.

In one embodiment, the at least one input radio-frequency signal and the at least one output radio-frequency signal are used for transmitting information between a cable TV service provider and at least one client.

To attain the foregoing objectives, another radio-frequency signal processing module capable of effectively removing power interference is proposed, including:

a module body;

a circuit board, placed inside the module body;

at least one broadband system power connector electrically coupled with the circuit board;

a plurality of radio-frequency connectors electrically coupled with the circuit board, used for receiving at least one input radio-frequency signal and providing at least one output radio-frequency signal; and

at least one broadband system filtering connector, each being used for coupling between one of the at least one broadband system power connector and a power source, wherein, the broadband system filtering connector has a space accommodating at least one filtering device so that interference of the power source can be attenuated and electromagnetic waves resulting from the interference can be dissipated outside the circuit board to promote a quality of the at least one output radio-frequency signal and reduce an electromagnetic emission over a frequency band. In one embodiment, the broadband system filtering connector has an axial metal contact part inside, and the axial metal contact part is a metal clamping piece or a metal pin.

In one embodiment, the broadband system filtering connector has a metal body.

In one embodiment, the filtering device includes an electromagnetic wave absorbing material, or the broadband system filtering connector has an electromagnetic wave absorbing material filled inside.

In one embodiment, the at least one input radio-frequency signal and the at least one output radio-frequency signal are used for transmitting information between a cable TV service provider and at least one client.

To make it easier for our examiner to understand the objective of the invention, its structure, innovative features, and performance, we use preferred embodiments together with the accompanying drawings for the detailed description of the invention.

### BRIEF DESCRIPTION OF THE DRAWINGS

FIG. 1 illustrates a radio-frequency signal processing module of prior art.

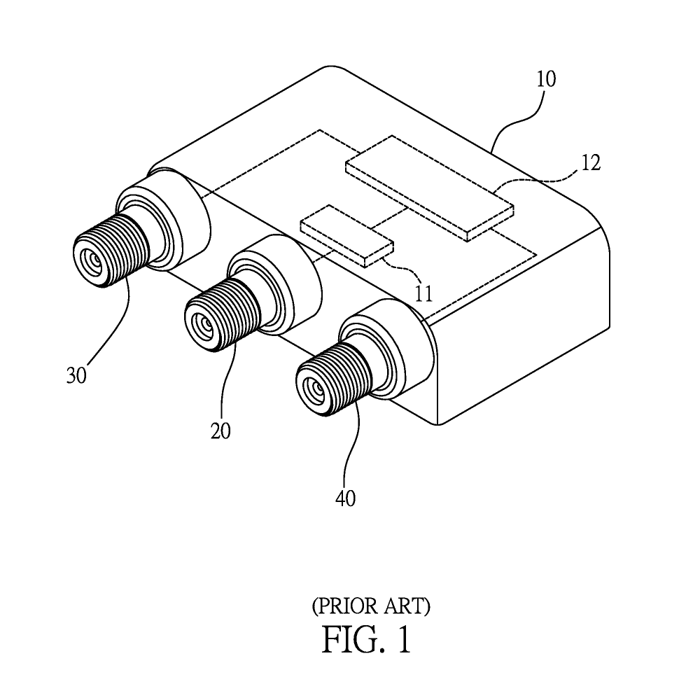

FIG. 2 illustrates one embodiment of the radio-frequency signal processing module capable of effectively removing power interference of the present invention.

FIG. 3 illustrates a scenario that a cylindrical connecting part of the radio-frequency signal processing module of FIG. 2 is connected with an F type connector of a power cable.

FIG. 4 illustrates a sectional view of the cylindrical connecting part and the F type connector of the power cable of FIG. 3 when they are connected with each other.

FIG. 5 illustrates a measured emission spectrum of a radio-frequency signal processing module using the proposal of the present invention in comparison with a measured emission spectrum of a radio-frequency signal processing module without the proposal of the present invention.

FIG. 6 illustrates another embodiment of the radio-frequency signal processing module capable of effectively removing power interference of the present invention.

### DETAILED DESCRIPTION OF THE PREFERRED EMBODIMENTS

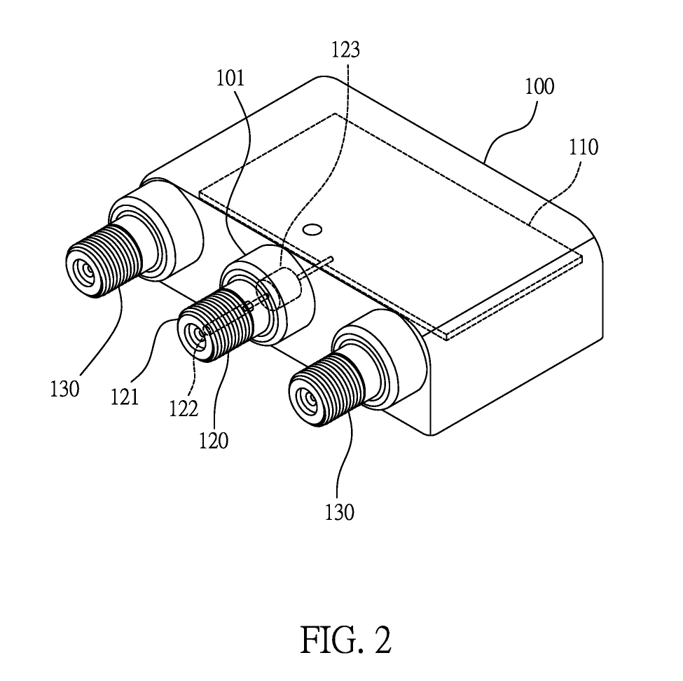

Please refer to FIG. 2, which illustrates one embodiment of the radio-frequency signal processing module capable of effectively removing power interference of the present invention, wherein, the radio-frequency signal processing module can be applied to a broadband system, which can be a cable TV system, an internet network, or a satellite communication system, etc.

As illustrated in FIG. 2, the radio-frequency signal processing module includes a module body 100, a circuit board 110, a broadband system power connector 120 and a plurality of radio-frequency connectors 130, wherein the broadband system power connector 120 refers to a power connector applicable to a cable TV system, an internet network, or a satellite communication system, etc.

The module body 100 is preferably a metal body to provide an electromagnetic wave shielding effect.

The circuit board 110 is placed inside the module body 100 to provide at least one radio-frequency signal processing function, for example (but not limited to) a radio-frequency signal amplifying function or a radio-frequency signal splitting function. Besides, the circuit board 110 can also have a power filtering device and/or an active element filtering device.

The broadband system power connector 120 is installed inside a port 101 of the module body 100, and the module body 100 can have a plurality of ports 101 accommodating a plurality of the broadband system power connectors 120 (although only one broadband system power connector 120 is shown in this embodiment).

Besides, although the port 101 has a ring-shaped flange in this embodiment, it can also have other shapes, and can be implemented with aluminum, zinc or other materials. The broadband system power connector 120 is used to couple with a power source to power the circuit board 110. In this embodiment, the broadband system power connector 120 is an F type power connector (it can also be an IEC type power connector or other similar types of power connectors), which has a cylindrical connecting part 121, an axial metal contact part 122 and at least one filtering device 123.

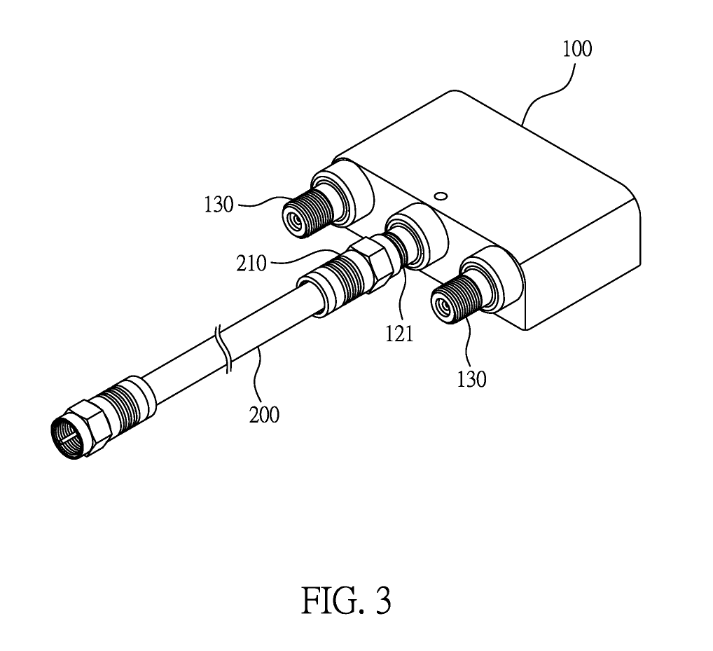

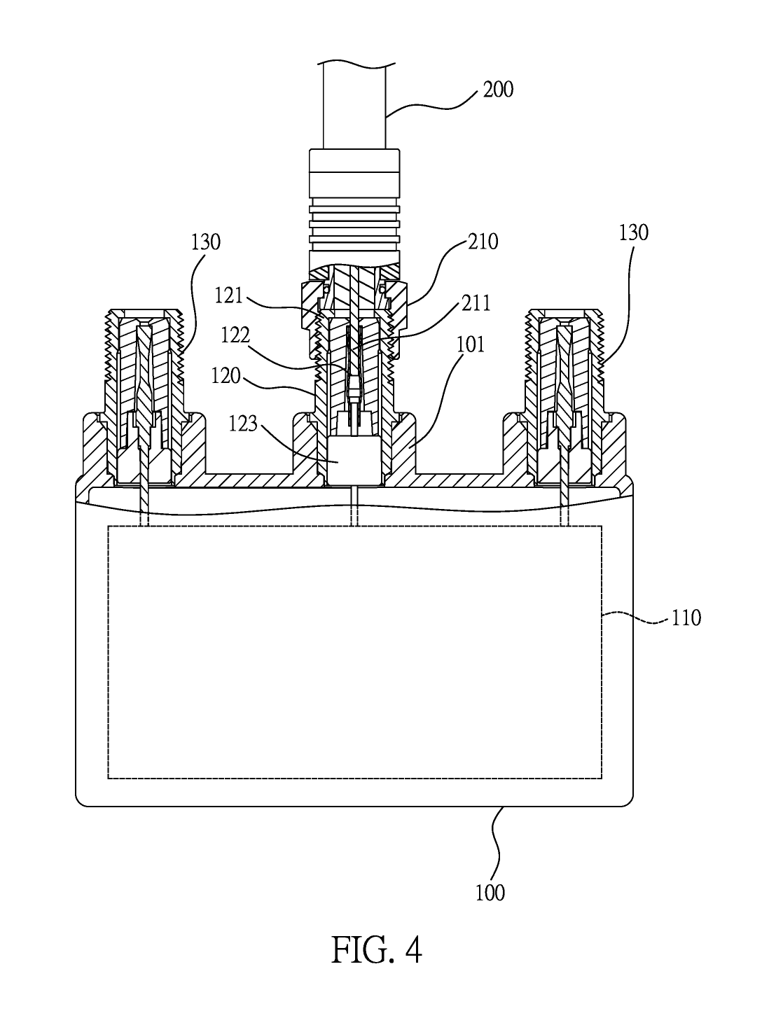

The cylindrical connecting part 121 is used for connecting with an F type connector of a power cable. Please refer to FIG. 3, which illustrates a scenario that the cylindrical connecting part 121 of the radio-frequency signal processing module of FIG. 2 is connected with an F type connector 210 of a power cable 200. Besides, please refer to FIG. 4, which illustrates a sectional view of the cylindrical connecting part 121 and the F type connector 210 of the power cable 200 of FIG. 3 when they are connected with each other. As illustrated in FIG. 4, the F type connector 210 has an axial metal pin 211 (male contact part) clamped by the axial metal contact part 122 (female contact part) to be electrically coupled with the axial metal contact part 122. Although the axial metal contact part 122 is a female contact part and the F type connector 210 has a male contact part in this embodiment, however, for an alternative embodiment, the axial metal contact part 122 can be changed to be a male contact part and the F type connector 210 can be changed to have a female contact part.

The axial metal contact part 122 can be a metal clamping piece (when the axial metal contact part 122 is a female connecting part) or a metal pin (when the axial metal contact part 122 is a male connecting part), and the material of which can include copper or gold.

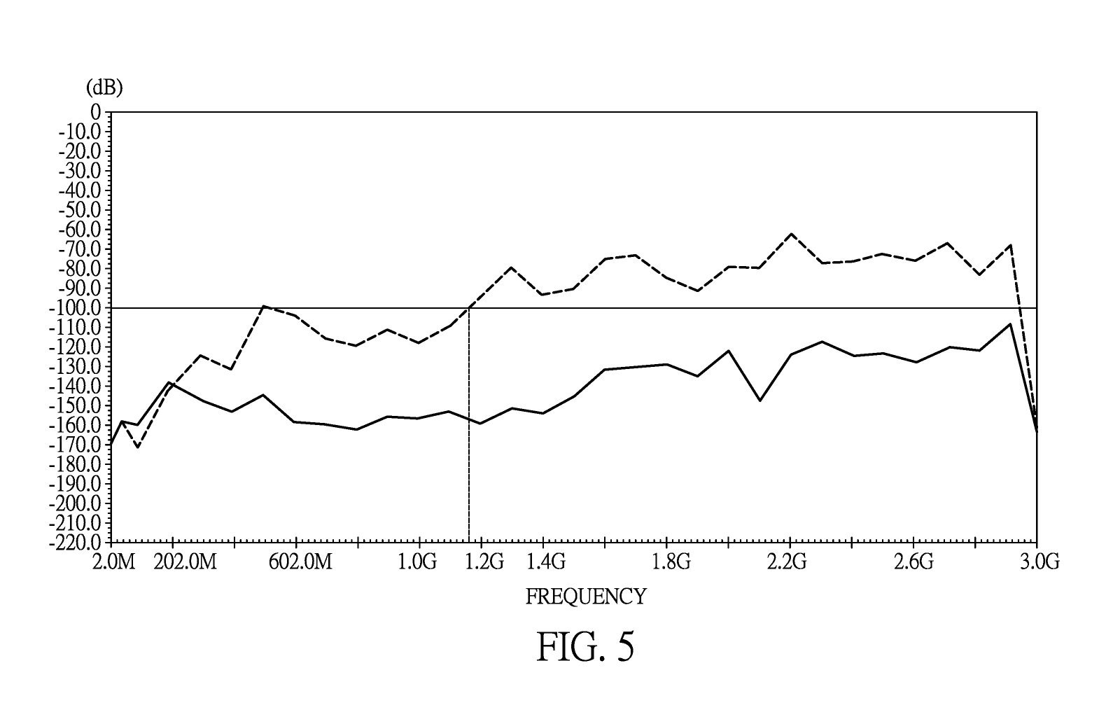

The filtering device 123, which can be an active device or a passive device, is disposed in an accommodating space of the broadband system power connector 120 and has a terminal coupled electrically with the axial metal contact part 122 and another terminal coupled electrically with the circuit board 110, so that interference of a power source can be effectively attenuated at the broadband system power connector 120 outside the circuit board 110 to promote the quality of radio-frequency signals. In addition, the electromagnetic wave energy resulting from the processing of the interference at the filtering device 123 can be dissipated by multiple reflections inside a closed region of the broadband system power connector 120 to reduce an electromagnetic emission over a frequency band. In addition, the filtering device 123 can further include an electromagnetic wave absorbing material or the broadband system power connector 120 can further have an electromagnetic wave absorbing material filled inside, so that electromagnetic waves can be dissipated by the electromagnetic wave absorbing material, which includes a conductive material and/or a magnetic permeable material to transfer the electromagnetic waves to heat. Please refer to FIG. 5, which illustrates a measured emission spectrum of a radio-frequency signal processing module using the proposal of the present invention in comparison with a measured emission spectrum of a radio-frequency signal processing module without the proposal of the present invention. As illustrated in FIG. 5, the measured emission spectrum of the radio-frequency signal processing module without the proposal of the present invention has emission levels exceeding a regulated level at frequencies above 1.2 GH_{Z}, while the measured emission spectrum of the radio-frequency signal processing module using the proposal of the present invention has all emission levels lowered down to below the regulated level within the frequency band from DC to 3.0 GH_{Z}.

Besides, the plurality of radio-frequency connectors 130 are electrically coupled with the circuit board 110 for receiving at least one input radio-frequency signal and providing at least one output radio-frequency signal, wherein the at least one input radio-frequency signal and the at least one output radio-frequency signal are used for transmitting information between a cable TV service provider and at least one client.

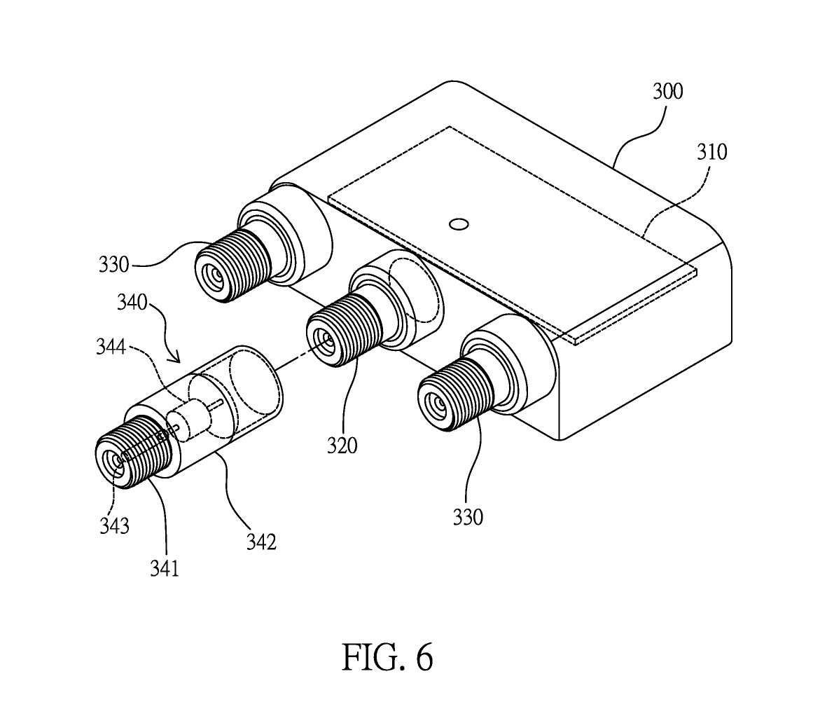

Please refer to FIG. 6, which illustrates another embodiment of the radio-frequency signal processing module capable of effectively removing power interference of the present invention, wherein, the radio-frequency signal processing module can be applied to a broadband system, which can be a cable TV system, an internet network, or a satellite communication system, etc..

As illustrated in FIG. 6, the radio-frequency signal processing module includes a module body 300, a circuit board 310, a broadband system power connector 320, a plurality of radio-frequency connectors 330, and a broadband system filtering connector 340, wherein the broadband system refers to a cable TV system, an internet network, or a satellite communication system, etc.

The module body 300 is preferably a metal body to provide an electromagnetic wave shielding effect.

The circuit board 310 is placed inside the module body 300 to provide at least one radio-frequency signal processing function, for example (but not limited to) a radio-frequency signal amplifying function or a radio-frequency signal splitting function.

The broadband system power connector 320 is used to couple with a power source to power the circuit board 310, and although only one broadband system power connector 320 is shown in this embodiment, there can be plural power connectors 320 in other embodiments of the present invention. In addition, although the broadband system power connector 320 is an F type power connector in this embodiment, it can also be an IEC type power connector or other similar types of power connectors in other embodiments.

The plurality of radio-frequency connectors 330 are electrically coupled with the circuit board 310 for receiving at least one input radio-frequency signal and providing at least one output radio-frequency signal, wherein the at least one input radio-frequency signal and the at least one output radio-frequency signal are used for transmitting information between a cable TV service provider and at least one client.

The broadband system filtering connector 340 has a cylindrical connecting part 341, a metal body 342, an axial metal contact part 343 and at least one filtering device 344. The broadband system filtering connector 340 is used to be coupled between the broadband system power connector 320 and a power source to provide a filtering effect and an electromagnetic wave dissipating effect when the power source supplies power to the circuit board 310.

The cylindrical connecting part 341 is used for connecting with an F type connector of a power cable, or can be a part of an F type connector of a power cable.

The metal body 342 can be a body containing copper or gold, and although it has a ring shape in this embodiment, it can also have a hexagon shape or other polygon shapes in other embodiments.

The axial metal contact part 343 can be a metal clamping piece or a metal pin, and the material of which can include copper or gold.

The filtering device 344, which can be an active device or a passive device, is disposed in an accommodating space of the metal body 342 and has a terminal coupled electrically with the axial metal contact part 343 and another terminal coupled electrically with the F type power connector 320, so that interference of a power source can be effectively attenuated outside the circuit board 310, and the quality of the at least one output radio-frequency signal can thereby be promoted. In addition, the electromagnetic wave energy resulting from the processing of the interference at the filtering device 344 can be dissipated by multiple reflections inside a closed region of the metal body 342 to substantially reduce an electromagnetic emission over a frequency band. In addition, the filtering device 344 can further include an electromagnetic wave absorbing material or the space between the metal body 342 and the filtering device 344 can be filled with an electromagnetic wave absorbing material filled, so that the electromagnetic waves can be further dissipated by the electromagnetic wave absorbing material, which includes a conductive material and/or a magnetic permeable material to transfer the electromagnetic waves to heat.

Thanks to the foregoing designs, the present invention possesses the following advantages:

1. The radio-frequency signal processing module of the present invention can promote the quality of a radio-frequency signal by filtering out interference of a power source with a broadband system power connector.

2. The radio-frequency signal processing module of the present invention can effectively reduce an electromagnetic emission over a frequency band by dissipating electromagnetic waves resulting from interference of a power source with a broadband system power connector.

3. The radio-frequency signal processing module of the present invention can promote the quality of a radio-frequency signal by filtering out interference of a power source with an add-on broadband system filtering connector.

4. The radio-frequency signal processing module of the present invention can effectively reduce an electromagnetic emission over a frequency band by dissipating electromagnetic waves resulting from interference of a power source with an add-on broadband system filtering connector.

5. The radio-frequency signal processing module of the present invention can also prevent radio-frequency noise from interfering with a power source.

While the invention has been described by way of example and in terms of preferred embodiments, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

In summation of the above description, the present invention herein enhances the performance over the conventional structure and further complies with the patent application requirements and is submitted to the Patent and Trademark Office for review and granting of the commensurate patent rights.

What is claimed is:

1. A radio-frequency signal processing module capable of effectively removing power interference, including:
a module body;
a circuit board, placed inside the module body;
at least one broadband system power connector, each being used for coupling with a power source via a power cable to power the circuit board; and
a plurality of radio-frequency connectors electrically coupled with the circuit board for receiving at least one input radio-frequency signal and providing at least one output radio-frequency signal;
wherein, the broadband system power connector has a space accommodating at least one filtering device so that interference of a power source can be attenuated and electromagnetic waves resulting from the interference can be dissipated outside the circuit board to promote a quality of the at least one output radio-frequency signal and reduce electromagnetic emission over a frequency band.

2. The radio-frequency signal processing module capable of effectively removing power interference as disclosed in claim 1, wherein the broadband system power connector has an axial metal contact part inside, and the axial metal contact part is a metal clamping piece or a metal pin.

3. The radio-frequency signal processing module capable of effectively removing power interference as disclosed in claim 1, wherein the module body has at least one port for installing the at least one broadband system power connector.

4. The radio-frequency signal processing module capable of effectively removing power interference as disclosed in claim 1, wherein the filtering device includes an electromagnetic wave absorbing material, or the broadband system power connector has an electromagnetic wave absorbing material filled inside.

5. The radio-frequency signal processing module capable of effectively removing power interference as disclosed in claim 1, wherein the at least one input radio-frequency signal and the at least one output radio-frequency signal are used for transmitting information between a cable TV service provider and at least one client.

6. A radio-frequency signal processing module capable of effectively removing power interference, including:
a module body;
a circuit board, placed inside the module body;
at least one broadband system power connector electrically coupled with the circuit board;
a plurality of radio-frequency connectors electrically coupled with the circuit board, used for receiving at least one input radio-frequency signal and providing at least one output radio-frequency signal; and
at least one broadband system filtering connector, each being used for coupling between one of the at least one broadband system power connector and a power source, wherein, the broadband system filtering connector has a space accommodating at least one filtering device so that interference of the power source can be attenuated and electromagnetic waves resulting from the interference can be dissipated outside the circuit board to promote a quality of the at least one output radio-frequency signal and reduce an electromagnetic emission over a frequency band.

7. The radio-frequency signal processing module capable of effectively removing power interference as disclosed in claim 6, wherein the broadband system filtering connector has an axial metal contact part inside, and the axial metal contact part is a metal clamping piece or a metal pin.

8. The radio-frequency signal processing module capable of effectively removing power interference as disclosed in claim 6, wherein the broadband system filtering connector has a metal body.

9. The radio-frequency signal processing module capable of effectively removing power interference as disclosed in claim 6, wherein the filtering device includes an electromagnetic wave absorbing material, or the broadband system filtering connector has an electromagnetic wave absorbing material filled inside.

10. The radio-frequency signal processing module capable of effectively removing power interference as disclosed in claim 6, wherein the at least one input radio-frequency signal and the at least one output radio-frequency signal are used for transmitting information between a cable TV service provider and at least one client.
